(19) United States
(12) Patent Application Publication
(10) Pub. No.: US 2026/0122962 A1
(43) Pub. Date: Apr. 30, 2026

(54) TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); George Dorman, Chandler, AZ (US)

(73) Assignee: Microchip Technology Incorporated, Chandler, AZ (US)

(21) Appl. No.: 19/003,181

(22) Filed: Dec. 27, 2024

Related U.S. Application Data
(60) Provisional application No. 63/676,026, filed on Jul. 26, 2024.

(51) Int. Cl. H10D 30/66; H10D 30/01; H10D 62/60; H10D 62/832; H10D 64/68

(52) U.S. Cl. CPC H10D 30/66; H10D 30/0291; H10D 62/60; H10D 62/8325; H10D 64/68

(57) ABSTRACT

A transistor comprising a silicon carbide drift layer formed on a silicon carbide substrate. A plurality of well implant layers formed within the silicon carbide drift layer. A plurality of source implant layers formed within a portion of each of the respective well implant layers. A first insulating layer formed over a portion of each of the respective well implant layers, the first insulating layer having a first thickness. A second insulating layer formed over a portion of the silicon carbide drift layer between the plurality of well implant layers. The second insulating layer having a second thickness, wherein the second thickness is greater than the first thickness. A gate formed over the first insulating layer and the second insulating layer.

### CROSS-REFERENCE TO RELATED APPLICATION

The present application claims priority to U.S. Provisional Patent Application No. 63/676,026, filed on Jul. 26, 2024, the contents of which are hereby incorporated by reference in their entirety.

### TECHNICAL FIELD

The present disclosure relates generally to transistors, and more specifically to power metal oxide semiconductor field effect transistors (MOSFETs) and methods for manufacturing same to improve the ruggedness of the transistor.

### SUMMARY

According to an aspect of one or more examples, there is provided a transistor that may include a silicon carbide substrate, a silicon carbide drift layer formed on the silicon carbide substrate, a plurality of well implant layers formed within the silicon carbide drift layer, a plurality of source implant layers formed within a portion of each of the respective well implant layers, a first insulating layer formed over a portion of each of the respective well implant layers, the first insulating layer having a first thickness, a second insulating layer formed over a portion of the silicon carbide drift layer between the plurality of well implant layers, the second insulating layer having a second thickness, wherein the second thickness is greater than the first thickness, and a gate formed over the first insulating layer and the second insulating layer. The transistor may include a silicon implant layer over the portion of the silicon carbide drift layer between the plurality of well implant layers. The silicon carbide substrate may comprise a first concentration of a first type dopant. The silicon carbide drift layer may comprise a second concentration of the first type dopant, the second concentration may be greater than the first concentration. The plurality of well implant layers may comprise a third concentration of a second type dopant. The plurality of source implant layers may comprise a fourth concentration of the first type dopant. The first type dopant may comprise an n-type dopant and the second type dopant may comprise a p-type dopant. The first type dopant may comprise a p-type dopant and the second type dopant may comprise an n-type dopant. The first insulating layer may comprise polysilicon, silicon dioxide or a mixture of polysilicon and silicon dioxide. The second insulating layer may comprise polysilicon, silicon dioxide or a mixture of polysilicon and silicon dioxide.

According to an aspect of one or more examples, there is provided method of manufacturing a transistor. The method may include providing a silicon carbide substrate, forming a silicon carbide drift layer on the silicon carbide substrate, forming a plurality of well implant layers within the silicon carbide drift layer, forming a plurality of source implant layers within a portion of each of the respective well implant layers, forming a first insulating layer over a portion of each of the respective well implant layers, the first insulating layer having a first thickness, forming a second insulating layer over a portion of the silicon carbide drift layer between the plurality of well implant layers, the second insulating layer having a second thickness, wherein the second thickness is greater than the first thickness, and forming a gate over the first insulating layer and the second insulating layer. The method may include forming a silicon implant layer over the portion of the silicon carbide drift layer between the plurality of well implant layers. The silicon carbide substrate may comprise a first concentration of a first type dopant. The silicon carbide drift layer may comprise a second concentration of the first type dopant, the second concentration may be greater than the first concentration. The plurality of well implant layers may comprise a third concentration of a second type dopant. The plurality of source implant layers may comprise a fourth concentration of the first type dopant. The first type dopant may comprise an n-type dopant and the second type dopant may comprise a p-type dopant. The first type dopant may comprise a p-type dopant and the second type dopant may comprise an n-type dopant. The first insulating layer may comprise polysilicon, silicon dioxide or a mixture of polysilicon and silicon dioxide. The second insulating layer may comprise polysilicon, silicon dioxide or a mixture of polysilicon and silicon dioxide.

### BRIEF DESCRIPTION OF DRAWINGS

FIG. 1 shows an illustration of a transistor according to one or more examples.

FIG. 2A is a cross sectional view of some of the steps in a method of manufacturing a transistor according to one or more examples.

FIG. 2B is a cross sectional view of some of the steps in a method of manufacturing a transistor according to one or more examples.

FIG. 2C is a cross sectional view of some of the steps in a method of manufacturing a transistor according to one or more examples.

FIG. 2D is a cross sectional view of some of the steps in a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

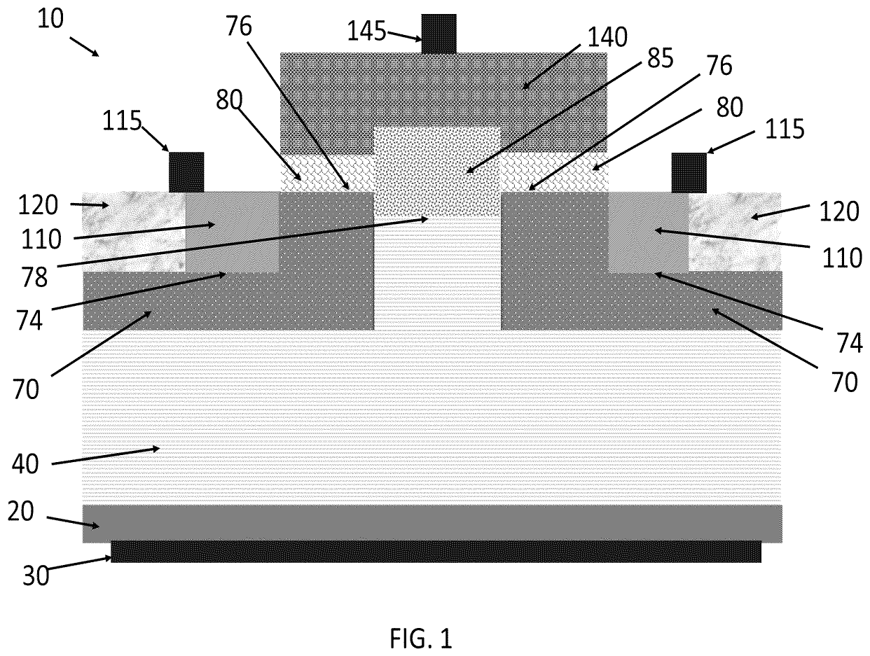

FIG. 1 shows an illustration of a transistor 10 according to one or more examples. Transistor 10 may represent, and may be called a power MOSFET, without limitation. Transistor 10 includes a gate contact 145 and a source contact 115 (may comprise a metal). The example transistor 10 (power MOSFET) of FIG. 1 includes a silicon carbide (SiC) substrate 20. The SiC substrate 20 shown in FIG. 1 may have a first concentration of a first type dopant, e.g., 5E18 (i.e. 5×10¹⁸). A silicon carbide drift layer 40 may be formed at one side of the SiC substrate 20 by creating a more heavily doped portion of the first type dopant (higher second concentration of first type dopant, e.g., a concentration of greater than 5E18) of the SiC substrate 20. The transistor 10 of FIG. 1 may also include a drain contact 30 formed at a first side of the SiC substrate 20, the first side of the SiC substrate 20 is opposite the second side of the SiC substrate 20 where the silicon carbide drift layer 40 is formed. The drain contact 30 may be made from a metal, polysilicon, or other suitable material. The example transistor 10 (power MOSFET) of FIG. 1 may include a plurality of well implant layers 70 that may be formed within the silicon carbide drift layer 40. The plurality of well implant layers 70 may comprise a third concentration of a second type dopant that may have a peak doping in the range 1E17 to 5E18 with a surface doping in the range 1E16 to 5E17. The example transistor 10 (power MOSFET) of FIG. 1 may include a plurality of source implant layers 110 that may be formed within a portion 74 of each of the respective well implant layers 70. The plurality of source implant layers 110 may comprise a fourth concentration of the first type dopant. The example transistor 10 (power MOSFET) of FIG. 1 may include a plurality of body implant layers 120 adjacent to the plurality of source implant layers 110. The example transistor 10 shown in FIG. 1 may include a plurality of source contacts 115 operatively connected to each of the respective plurality of source implant layers 110 and to each of the respective plurality of body layer implant layers 120. The plurality of source contacts 115 may be made from a metal, polysilicon, or other suitable material. The transistor 10 of FIG. 1 may also include a first insulating layer 80 formed over a portion 76 of the respective well implant layer 70. The first insulating layer 80 may comprise a first thickness. The first insulating layer 80 may comprise polysilicon, silicon dioxide or a mixture of polysilicon and silicon dioxide. The transistor 10 of FIG. 1 may also include a second insulating layer 85 formed over a portion 78 of the silicon carbide drift layer 40. The second insulating layer 85 may comprise a second thickness. The second thickness of the second insulating layer 85 may be greater than the first thickness of the first insulating layer 80. The combination of the second thickness of the second insulating layer 85 with the first thickness of the first insulating layer 80 creates a thicker gate oxide which improves the ruggedness of the transistor 10. The second insulating layer 85 may comprise polysilicon, silicon dioxide or a mixture of polysilicon and silicon dioxide. The transistor of FIG. 1 may also include a gate 140 formed over the first insulating layer 80 and over the second insulating layer 85. The gate 140 may be made from a metal, polysilicon, or other suitable material.

In the example transistor 10 of FIG. 1, the first type dopant may be an n-type dopant with the second type dopant being a p-type dopant. Alternatively, the first type dopant may be a p-type dopant with the second type dopant being an n-type dopant.

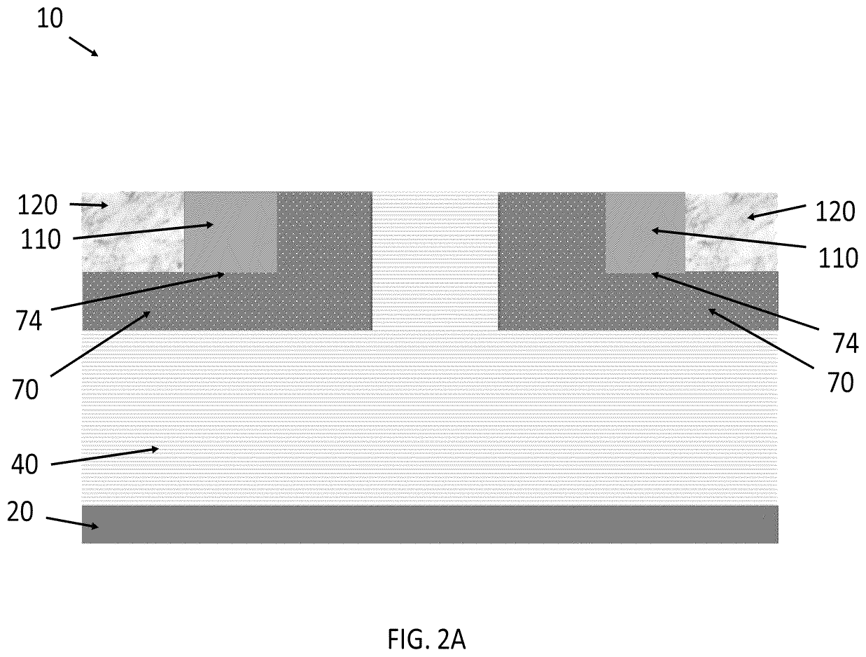

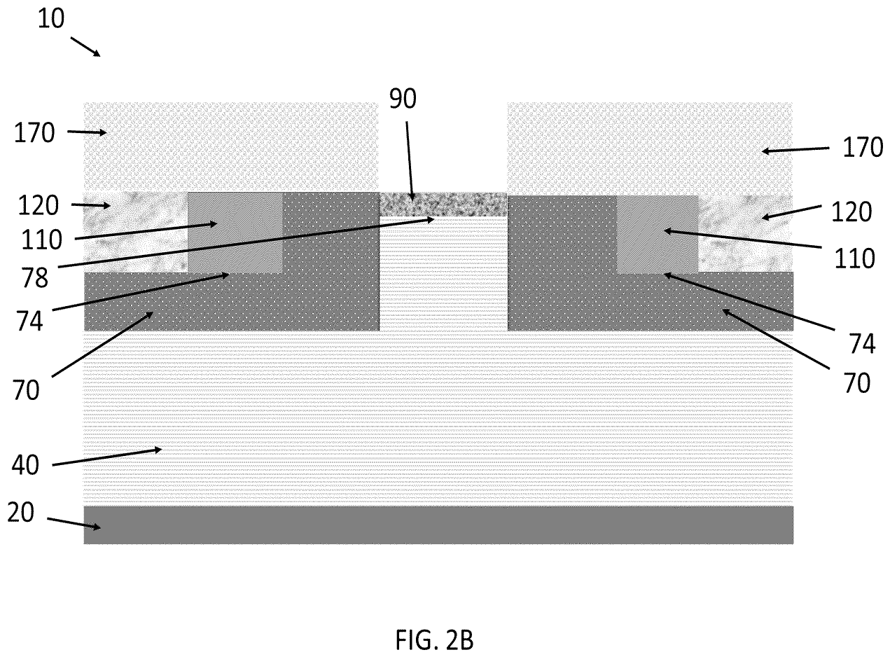

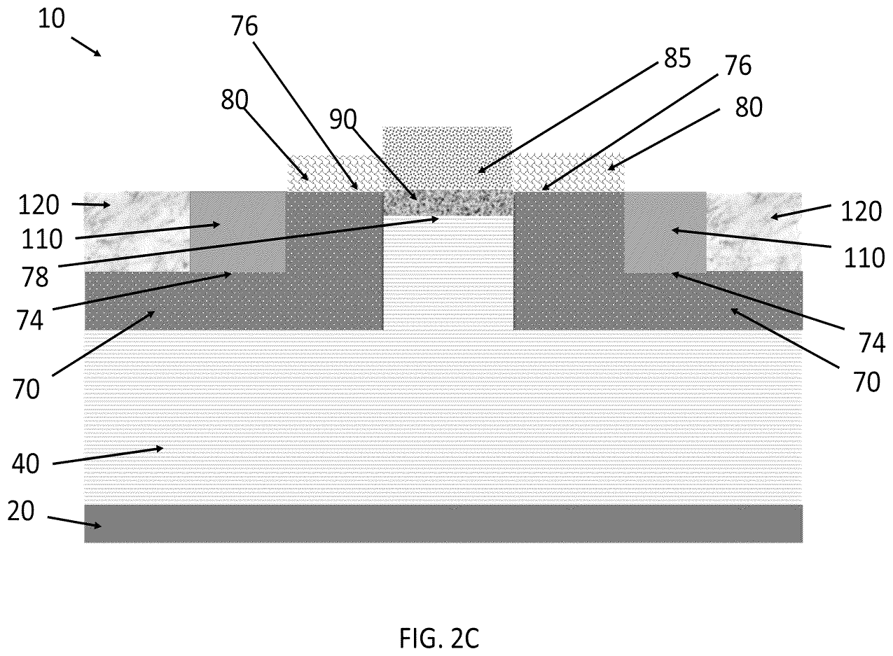

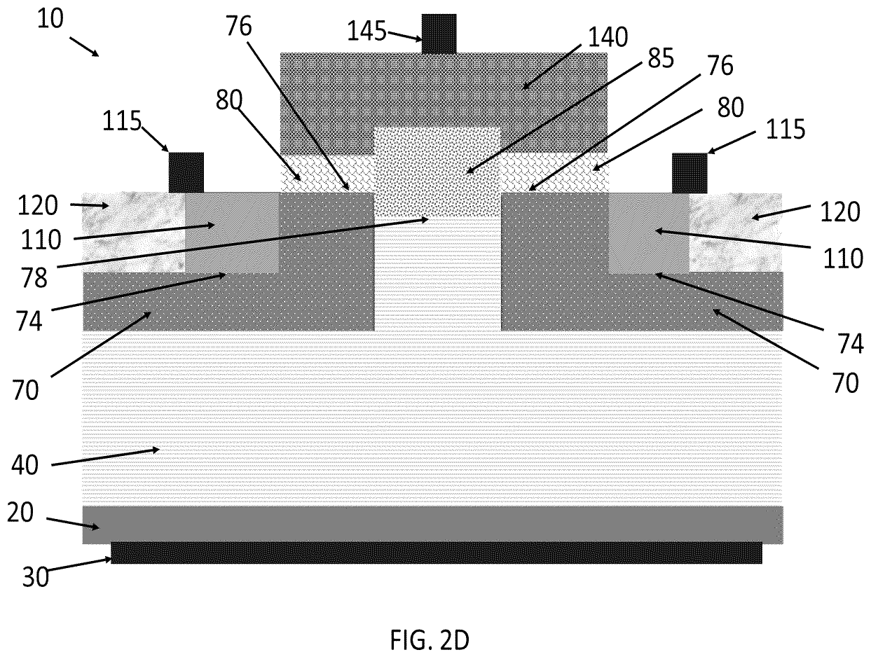

FIGS. 2A-2D show a method of manufacturing transistor 10 according to one or more examples. Although the example method shown in FIGS. 2A-2D include steps shown in a particular order, the steps may be performed in a different order, and may include additional steps that are not explicitly shown.

FIG. 2A is a cross sectional view of some of the steps in a method of manufacturing a transistor 10 according to one or more examples. In FIG. 2A, the example method may include providing a silicon carbide substrate 20 that may have a first concentration of a first type dopant, e.g., 5E18 (i.e. 5×10¹⁸). In FIG. 2A, the example method may include forming a silicon carbide drift layer 40 on the silicon carbide substrate 20. The silicon carbide drift layer 40 may have a second concentration of the first type dopant. The silicon carbide drift layer 40 may be formed by a more heavily doped portion (higher second concentration of first type dopant, e.g., a concentration of greater than 5E18) of the silicon carbide substrate 20. The example method may include forming a plurality of well implant layers 70 within the silicon carbide drift layer 40. The plurality of well implant layers 70 may comprise a third concentration of a second type dopant that may have a peak doping in the range 1E17 to 5E18 with a surface doping in the range 1E16 to 5E17. The example method may include forming a plurality of source implant layers 110 that may be formed within a portion 74 of each of the respective well implant layers 70. The plurality of source implant layers 110 may comprise a fourth concentration of the first type dopant and may have a concentration in the range of 1E18-1E20. The example method may include forming a plurality of body implant layers 120 adjacent to the plurality of source implant layers 110. The example method may include forming a source implant layer.

FIG. 2B is a cross sectional view of some of the steps in a method of manufacturing a transistor 10 according to one or more examples. In FIG. 2B, a masking layer 170 may be formed over the plurality of well implant layers 70, over the plurality of source implant layers 110 and over the plurality of body implant layers 120. The example method may include implanting silicon 90 into a portion 78 of the silicon carbide drift layer 40 that is exposed within the masking layer 170.

FIG. 2C is a cross sectional view of some of the steps in a method of manufacturing a transistor 10 according to one or more examples. In FIG. 2C, a first insulating layer 80, e.g. gate oxide layer, may be formed over a portion 76 of the respective well implant layer 70. The first insulating layer 80 may comprise a first thickness. The first insulating layer 80 may comprise polysilicon, silicon dioxide or a mixture of polysilicon and silicon dioxide. In addition, the example method may include forming a second insulating layer 85, e.g. thicker gate oxide, using the implanted silicon 90 from within a portion 78 of the silicon carbide drift layer 40. The second thickness of the second insulating layer 85 may be greater than the first thickness of the first insulating layer 80. The combination of the second thickness of the second insulating layer 85 with the first thickness of the first insulating layer 80 creates a thicker gate oxide which improves the ruggedness of the transistor 10. The second insulating layer 85 may comprise polysilicon, silicon dioxide or a mixture of polysilicon and silicon dioxide.

FIG. 2D is a cross sectional view of some of the steps in a method of manufacturing a transistor 10 according to one or more examples. In FIG. 2D, the example method may include forming a gate 140 over the first insulating layer 80 and over the second insulating layer 85. The gate 140 may be made from a metal, polysilicon, or other suitable material. A gate contact 145 may be formed and operatively connected to the gate 140. The gate contact 145 may be made of metal. A plurality of source contacts 115 may be formed and operatively connected to each of the respective plurality of source implant layers 110 and to each of the respective plurality of body layer implant layers 120. The plurality of source contacts 115 may be made from a metal, polysilicon, or other suitable material. A drain contact 30 may be formed at an opposite side to the drift layer 40 on the silicon carbide substrate 20. The drain contact 30 may be made from a metal, polysilicon, or other suitable material.

The example method of manufacturing transistor 10 of FIGS. 2A-2D may have the first type dopant be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a silicon carbide substrate;
a silicon carbide drift layer formed on the silicon carbide substrate;
a plurality of well implant layers formed within the silicon carbide drift layer;
a plurality of source implant layers formed within a portion of each of the respective well implant layers;
a first insulating layer formed over a portion of each of the respective well implant layers, the first insulating layer having a first thickness;
a second insulating layer formed over a portion of the silicon carbide drift layer between the plurality of well implant layers, the second insulating layer having a second thickness, wherein the second thickness is greater than the first thickness; and
a gate formed over the first insulating layer and the second insulating layer.

2. The transistor of claim 1 comprising a silicon implant layer over the portion of the silicon carbide drift layer between the plurality of well implant layers.

3. The transistor of claim 1, wherein the silicon carbide substrate comprises a first concentration of a first type dopant.

4. The transistor of claim 3, wherein the silicon carbide drift layer comprises a second concentration of the first type dopant.

5. The transistor of claim 4, wherein the plurality of well implant layers comprises a third concentration of a second type dopant.

6. The transistor of claim 5, wherein the plurality of source implant layers comprises a fourth concentration of the first type dopant.

7. The transistor of claim 6, wherein the first type dopant comprises an n-type dopant and the second type dopant comprises a p-type dopant.

8. The transistor of claim 6, wherein the first type dopant comprises a p-type dopant and the second type dopant comprises an n-type dopant.

9. The transistor of claim 1, wherein the first insulating layer comprises polysilicon, silicon dioxide or a mixture of polysilicon and silicon dioxide.

10. The transistor of claim 9, wherein the second insulating layer comprises polysilicon, silicon dioxide or a mixture of polysilicon and silicon dioxide.

11. A method of manufacturing a transistor, the method comprising:
providing a silicon carbide substrate;
forming a silicon carbide drift layer on the silicon carbide substrate;
forming a plurality of well implant layers within the silicon carbide drift layer;
forming a plurality of source implant layers within a portion of each of the respective well implant layers;
forming a first insulating layer over a portion of each of the respective well implant layers, the first insulating layer having a first thickness;
forming a second insulating layer over a portion of the silicon carbide drift layer between the plurality of well implant layers, the second insulating layer having a second thickness, wherein the second thickness is greater than the first thickness; and
forming a gate over the first insulating layer and the second insulating layer.

12. The method of claim 11 comprising forming a silicon implant layer over the portion of the silicon carbide drift layer between the plurality of well implant layers.

13. The method of claim 11, wherein the silicon carbide substrate comprises a first concentration of a first type dopant.

14. The method of claim 13, wherein the silicon carbide drift layer comprises a second concentration of the first type dopant.

15. The method of claim 14, wherein the plurality of well implant layers comprises a third concentration of a second type dopant.

16. The method of claim 15, wherein the plurality of source implant layers comprises a fourth concentration of the first type dopant.

17. The method of claim 16, wherein the first type dopant comprises an n-type dopant and the second type dopant comprises a p-type dopant.

18. The method of claim 16, wherein the first type dopant comprises a p-type dopant and the second type dopant comprises an n-type dopant.

19. The method of claim 11, wherein the first insulating layer comprises polysilicon, silicon dioxide or a mixture of polysilicon and silicon dioxide.

20. The method of claim 19, wherein the second insulating layer comprises polysilicon, silicon dioxide or a mixture of polysilicon and silicon dioxide.
